(19) United States
(12) Patent Application Publication
(10) Pub. No.: US 2015/0330772 A1
(43) Pub. Date: Nov. 19, 2015

(54) Proximity Sensor Having a Daughterboard-Mounted Light Detector

(71) Applicants: Nataporn Charusabha, Bangkok (TH); Noppadol Keawcharoensook, Bangkok (TH)

(72) Inventors: Nataporn Charusabha, Bangkok (TH); Noppadol Keawcharoensook, Bangkok (TH)

(21) Appl. No.: 14/279,214

(22) Filed: May 15, 2014

(51) Int. Cl. G01B 11/14; H05K 3/36; H05K 3/32

(52) U.S. Cl. CPC G01B 11/14; H05K 3/32; H05K 3/36

(57) ABSTRACT

A proximity sensor comprising a light emitter and light detector each encapsulated by a molded light transmissive component. The light transmissive components can be separated by a molded light blocking component, and the light detector can be mounted on a daughterboard, such that the light blocking component and daughterboard can inhibit the transmission of light between the light emitter and light detector to limit crosstalk.

### BACKGROUND

1. Field of the Invention

The present disclosure relates to proximity, gesture, and/or motion sensors, particularly optical sensors having molded infrared light transmissive and blocking components.

2. Background

Proximity, gesture, and motion sensors are often used in a variety of devices, including mobile phones, personal media players, tablet computers, laptop computers, amusement and vending machines, industrial machinery, contactless switches, automated sanitary machinery, and other devices. By way of a non-limiting example, some mobile phones incorporate a proximity sensor near the mobile phone's touchscreen so that the screen can be turned off to save power and to avoid unwanted touch inputs when the mobile phone is being used and a user's head is near to the screen or is touching the screen.

FIG. 1 depicts a prior art optical proximity sensor 100. Optical proximity sensors 100 can comprise one or more light emitters 102 and one or more light detectors 104. In some embodiments, the light emitters 102 can be light emitting diodes (LEDs) that emit infrared light, and the light detectors 104 can be photodiodes configured to detect infrared light. As can be seen from FIG. 1, when an object 108 is located proximate to the optical proximity sensor 100, infrared light 106 emitted by the light emitter 102 can be reflected off of the object 108 and be directed back toward the light detector 104. The reflected rays of infrared light 106 can be detected by the light detector 104, which can provide an indication that the object 108 is proximate to the optical proximity sensor 100, and/or can provide information about the motion of the object 108 relative to the optical proximity sensor 100 such that the optical proximity sensor 100 can act as a motion sensor or gesture sensor.

Crosstalk can be undesirable interaction between the light emitters 102 and light detectors 104 in optical proximity sensors 100. Crosstalk can occur when light travels directly or indirectly from the light emitter 102 to the light detector 104 without being reflected off of a nearby object 108, thereby leading to false positives in motion or proximity detection. To decrease the level of crosstalk between the light emitters 102 and light detectors 104, many optical proximity sensors 100 have one or more blocking components 110 placed or formed between the light emitters 102 and light detectors 104 to block at least some non-reflected light transmission between the light emitters 102 and the light detectors 104.

In many optical proximity sensors 100, the blocking component 110 can be a shield, such as a metal shield or a shield of any other material that blocks the transmission of infrared light. Shields are often manufactured separately, and are placed between the light emitter 102 and light detector 104 during assembly of the optical proximity sensor 100. However, the use of a separately manufactured metal shield can add manufacturing expenses due to the materials cost of the metal or other infrared-blocking material, the often small size of the shields, and the cost of custom machinery to form the shield and to place the shield during assembly. Additionally, the shield can be dented or deformed during use, or can come loose and be displaced from the rest of the optical proximity sensor 100. As the placement and structural form of the blocking component 110 can be important in inhibiting light transfer in certain directions to limit crosstalk, deformation or displacement of the shield can lead to decreased performance of the optical proximity sensor 100 by allowing higher levels of crosstalk.

In other optical proximity sensors 100, the blocking component 110 can be a light blocking compound that is molded and cured into position between the light emitter 102 and light detector 104. In some embodiments, the light emitter 102 and light detector 104 can be encapsulated in molded and cured light transmissive compounds, and the light blocking compound can be molded around the light transmissive compounds and into a space between the light emitter 102 and light detector 104. In other embodiments, the light emitter 102 and/or light detector 104 can be mounted on a pre-molded plastic leadframe, and an infrared light transmissive gel can fill the cavities above the light emitter 102 and light detector 104. However, the coating of infrared light transmissive gel can be inconsistent and is often unable to be formed into a dome shaped lens for emitting or receiving infrared light.

While these molded embodiments can avoid the use of separate shields, they often do not fully block transmission of light from the light emitter 102 to the light detector 104, leading to undesirable crosstalk. For example, in some embodiments the light emitter 102 and light detector 104 are mounted on a leadframe or base layer that allows at least some transmission of infrared light, such that at least a portion of the infrared light emitted by the light emitter 102 can pass through the leadframe or base layer and be detected by the light detector 104.

What is needed is an optical proximity sensor 100 comprising molded light transmissive and light blocking components, in which the light detector 104 is positioned on a daughterboard that can block at least a portion of light from passing through the daughterboard from below and into the light detector 104.

### BRIEF DESCRIPTION OF THE DRAWINGS

FIG. 1 depicts a prior art proximity sensor.

FIG. 2 depicts an embodiment of a proximity sensor comprising a daughterboard underneath a light detector.

FIG. 3A depicts a top view of an embodiment of a proximity sensor.

FIG. 3B depicts a bottom view of an embodiment of a proximity sensor.

FIG. 3C depicts a side view of an embodiment of a proximity sensor.

FIG. 3D depicts a front view of an embodiment of a proximity sensor.

FIG. 4A depicts light paths through an embodiment of a proximity sensor without a daughterboard underneath a light detector.

FIG. 4B depicts light paths through an embodiment of a proximity sensor comprising a daughterboard underneath a light detector.

FIG. 5 depicts a flow chart of a method of assembling embodiments of a proximity sensor.

FIG. 6A depicts a first stage of assembling a proximity sensor.

FIG. 6B depicts a second stage of assembling a proximity sensor.

FIG. 6C depicts a third stage of assembling a proximity sensor.

FIG. 6D depicts an assembled proximity sensor.

FIG. 7 depicts a flow chart of a second method for manufacturing embodiments of a proximity sensor.

FIG. 8 depicts a flow chart of a third method for manufacturing embodiments of a proximity sensor.

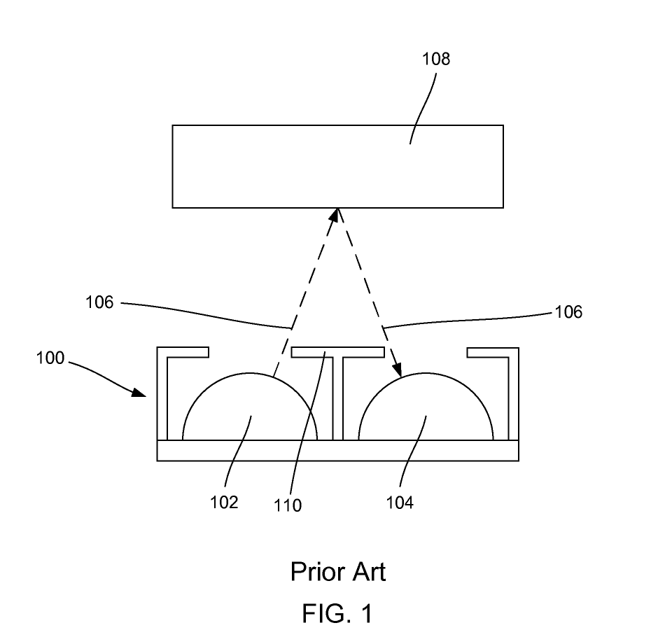

### DETAILED DESCRIPTION

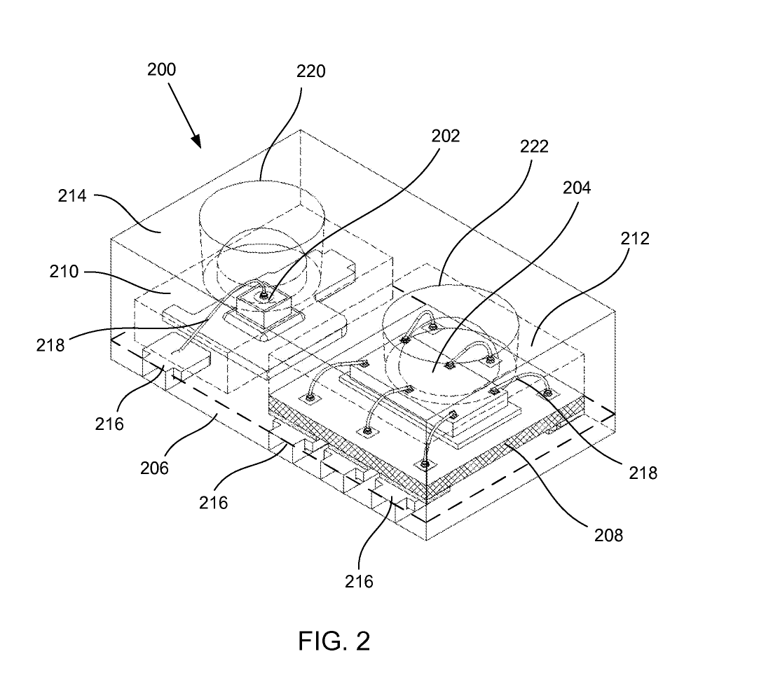

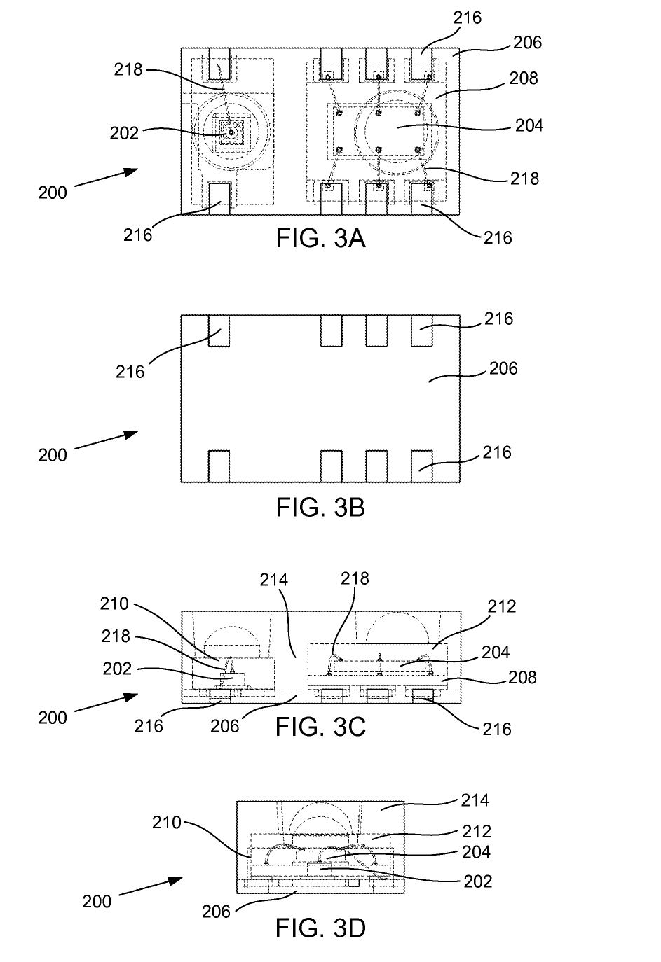

FIG. 2 depicts an angled view of an embodiment of a proximity sensor 200. FIGS. 3A-3D respectively depict a top view, a bottom view, a side view, and a front view of an embodiment of the proximity sensor 200. The proximity sensor 200 can comprise a light emitter 202, a light detector 204, a base 206, a daughterboard 208, a first light transmissive component 210, a second light transmissive component 212, and a light blocking component 214.

The light emitter 202 can be a light source configured to emit light. In some embodiments, the light emitter 202 can be configured to emit infrared light. By way of a non-limiting example, in some embodiments the light emitter 202 can be an infrared light emitting diode (IR LED). In alternate embodiments, the light emitter 202 can be an emitter die configured to emit light at any desired wavelength or range of wavelengths within the electromagnetic spectrum. The light emitter 202 can be a bare die, prepackaged die, and/or any other type of die.

The light detector 204 can be a photodiode or other light detector configured to detect light entering the light detector 204. In some embodiments, the light detector 204 can be configured to detect infrared light. By way of a non-limiting example, in some embodiments the light detector 204 can be an infrared-responding photodiode configured to detect infrared light. In some embodiments, a light detector 204 can comprise an integrated circuit configured to detect direct or reflected light entering the light detector 204.

The base 206 can be a substrate upon which other components of the proximity sensor 200 can be mounted. In some embodiments, the base 206 can be a leadframe comprising conductive material such as metal. In other embodiments, the base 206 can be a substrate of organic material, epoxy molding compound, or any other desired material. By way of non-limiting examples, the base 206 can comprise a laminated substrate such as an FR-4 epoxy-based laminate or a resin-based BT (Bismaleimide-Triazine) epoxy.

In some embodiments, the base 206 can comprise one or more leads 216 or metal trace I/O components positioned within the base 206. The base 206 and/or individual leads 216 can comprise one or more substrates of conductive material configured to allow an electrical connection between components that are coupled with the leads 216. In some embodiments, the base 206 and/or leads 216 can comprise copper alloy. In other embodiments, the base 206 and/or leads 216 can comprise other types of metal and/or metal alloys, such as copper, ferrous alloys, nickel, cobalt, chromium, nickel alloys, silver, and/or gold, or any other conductive material.

In some embodiments, each individual lead 216 can be separated from other leads 216 by non-conductive material, such as a molding compound, such that one lead 216 is not directly electrically connected to the other leads 216 within the proximity sensor 200. By way of a non-limiting example, in some embodiments each individual lead 216 can be separated from other leads 216 by a black molding compound within the base 206. In other embodiments, one or more leads 216 can be contiguous with one or more other leads 216 within the base 206.

In some embodiments, the base 206 can comprise material that can inhibit light transmission, such that it blocks at least some level of light transmission through the base 206. By way of a non-limiting example, the material between the leads 216 of the base 206 can inhibit the transmission of infrared light through the base 206. By way of non-limiting examples, the base 206 can comprise a black molding compound in the spaces between the leads 216. In some embodiments, the material between the leads 216 of the base can be an extension of the light blocking component 214, while in other embodiments the base 206 can be formed separately.

The leads 216 can extend to or beyond the exterior of the proximity sensor 200, such that the leads 216 can be electrically coupled with other components exterior to the proximity sensor 200. By way of a non-limiting example, the leads 216 of the proximity sensor 200 can be electrically coupled with components of a mobile phone to integrate the proximity sensor 200 into the mobile phone. FIG. 3B depicts a bottom view of an exemplary embodiment of the proximity sensor 200, with eight leads 216 exposed as mounting pads on the underside of the proximity sensor 200, however other embodiments can have any other number of leads 216 exposed or extending from the proximity sensor 200.

The daughterboard 208 can be a substrate coupled with the light detector 204 and the base 206. In some embodiments, the daughterboard 208 can comprise conductive material configured to allow an electrical connection between components that are coupled with the daughterboard 208. As shown in FIG. 2, in some embodiments the daughterboard 208 can be mounted on the base 206 and the light detector 204 can be mounted on the top surface of the daughterboard 208, such that the daughterboard 208 is positioned between the light detector 204 and the base 206. The daughterboard 208 can comprise optically non-transmissive material configured to block the transmission of infrared light. In some embodiments, the daughterboard 208 can comprise organic and/or epoxy-based material, such as organic coatings or compounds, similar to that used in printed circuit boards (PCBs). By way of non-limiting examples, the daughterboard 208 can comprise an FR-4 epoxy-based material, a resin-based BT (Bismaleimide-Triazine) epoxy, or other epoxy-based material.

The light emitter 202 and light detector 204 can each be electrically coupled with one or more leads 216. The light emitter 202 can be directly coupled to leads 216 via wirebonding 218, conductive solder, or other electrical connections, as shown in FIGS. 2, 3A and 3C-D. In some embodiments, the light detector 204 can be indirectly coupled with the leads 216 via wirebonding 218 to conductive elements of the daughterboard 208, and from the daughterboard 208 to the leads 216, as shown in FIGS. 2, 3A and 3C-D. In alternate embodiments, the daughterboard 208 can define one or more apertures, and wirebonding 218 or other electrical connections from the light detector 204 directly to the leads 216 can pass through the apertures in the daughterboard 208.

The first and second light transmissive components 210 and 212 can each comprise an optically transmissive material configured to allow a spectrum of light to pass through the optically transmissive material. By way of a non-limiting example, the first and second light transmissive components 210 and 212 can be configured to allow infrared light to pass through the optically transmissive material. In some embodiments, the first and second light transmissive components 210 and 212 can comprise infrared pass optoelectronic epoxy. In other embodiments, the first and second light transmissive components 210 and 212 can comprise a clear transfer molding compound, or other optically transmissive epoxies, plastics, polymers, or other materials. By way of non-limiting examples, in some embodiments the first and second light transmissive components 210 and 212 can be formed from clear epoxy material in a tablet form applied to the components of the proximity sensor 200 using transfer molding, or in a liquid form applied to the components using a casting process.

The first light transmissive component 210 can extend over and around the light emitter 202, such that the light emitter 202 is encapsulated by the first light transmissive component 210. In some embodiments, the first light transmissive component 210 can be formed with a dome or lens above the light emitter 202, as shown in FIG. 3C. In other embodiments, the first light transmissive component 210 can extend to the top surface of the proximity sensor 200.

The second light transmissive component 212 can extend over and around the light detector 204, such that the light detector 204 is encapsulated by the second light transmissive component 212. In some embodiments, the second light transmissive component 212 can be formed with a dome or lens above the light detector 204, as shown in FIG. 3C. In other embodiments, the second light transmissive component 212 can extend to the top surface of the proximity sensor 200. As shown in FIG. 2, in some embodiments the base of the second light transmissive component 212 can have substantially the same dimensions of the daughterboard 208, such that the second light transmissive component extends over the top surface of the daughterboard 208. In some embodiments, the combination of the second light transmissive component 212, the light detector 204, and the daughterboard 208 can be referred to as a light detector module.

In some embodiments, the first light transmissive component 210 can extend below the light emitter 202 to at least partially fill space between one or more leads 216 of the base 206, including the spaces between leads 216 underneath the daughterboard 208. The daughterboard 208 can be positioned above the extension of the first light transmissive component 210, such that the daughterboard 208 separates the first light transmissive component 210 from the second light transmissive component 212 above the daughterboard 208.

The light blocking component 214 can comprise an optically non-transmissive material configured to block the transmission of some or all of a spectrum of light through the optically non-transmissive material. By way of a non-limiting example, the light blocking component 214 can be configured to block some or all transmission of infrared light through the light blocking component 214. In some embodiments, the light blocking component 214 can comprise an infrared-blocking, filtering, or cutting transfer molding epoxy compound, such as a black molding compound. In other embodiments, the light blocking component 214 can comprise an infrared filter optoelectronic epoxy, or other optically non-transmissive epoxies, plastics, polymers, or other material.

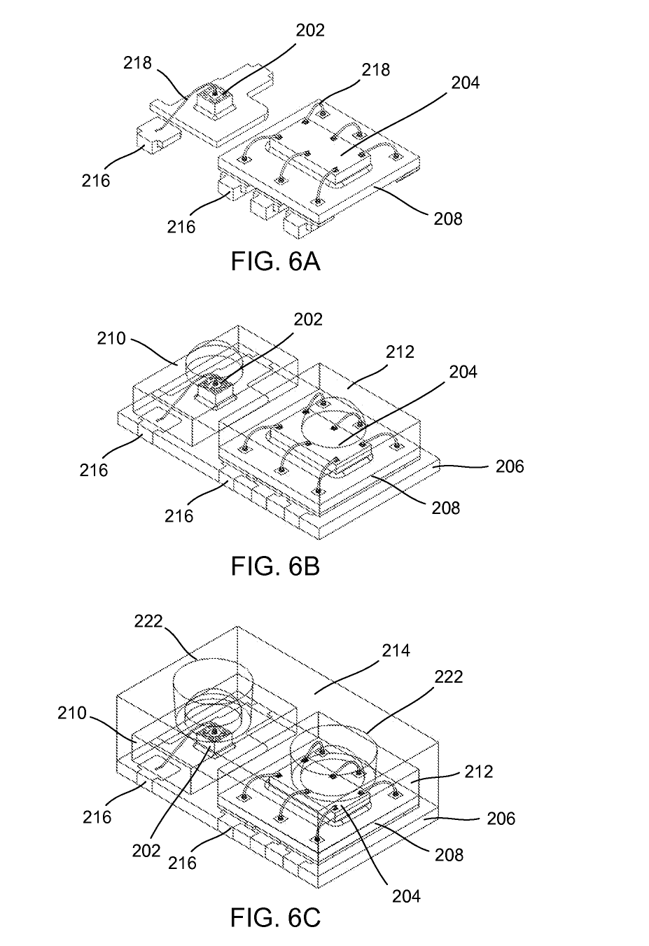

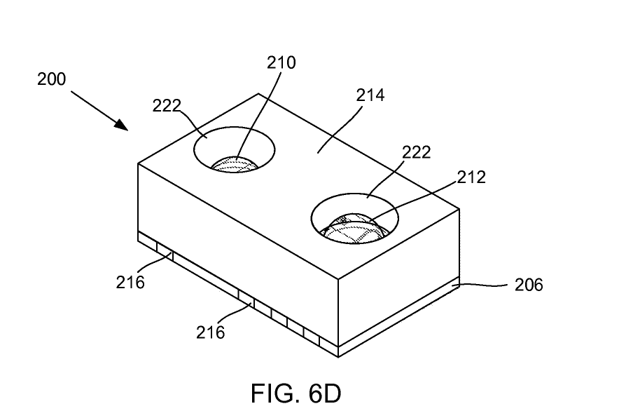

The light blocking component 214 can extend over and around the base 206, the first and second light transmissive components 210 and 212, and the daughterboard 208. In some embodiments, the light blocking component 214 can also form the exterior surfaces of the proximity sensor 200. In some embodiments, the light blocking component 214 can further extend below the light emitter 202, light detector 204 and/or daughterboard 208 to at least partially fill space between one or more leads 216 within the base 206, including the spaces between leads 216 underneath the daughterboard 208. In FIG. 2, the light blocking component 214 is shown as transparent to illustrate components inside the proximity sensor 200, but in some embodiments the light blocking component 214 can be opaque, as shown in FIG. 6D.

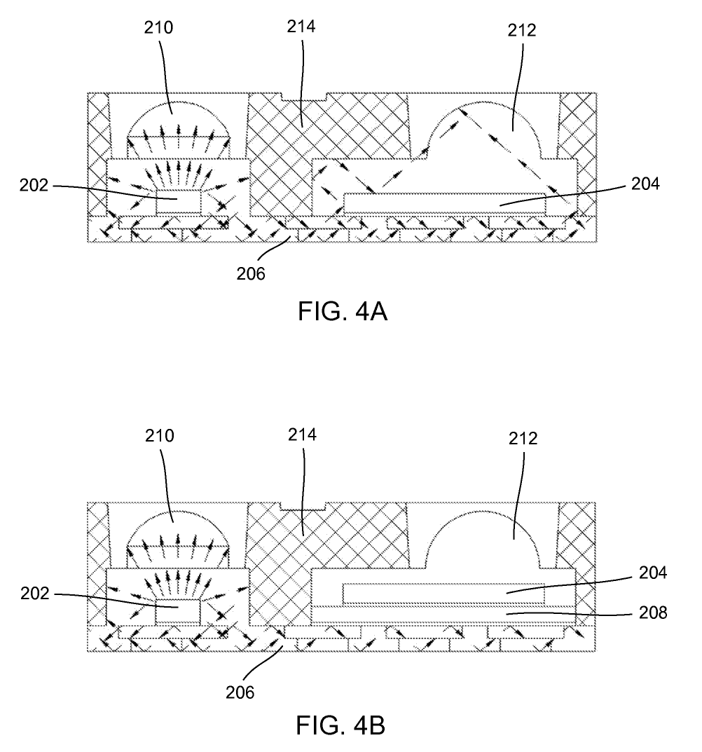

The light blocking component 214 can fill the space between the first and second light transmissive components 210 and 212, such that light emitted by the light emitter 202 that travels directly toward the light detector 204 can substantially be blocked by the optically non-transmissive material of the light blocking component 214, thereby avoiding a level of crosstalk between the light emitter 202 and light detector 204. By way of a non-limiting example, the light blocking component 214 can be configured to block the transmission of infrared light, thereby blocking the transmission of some or substantially all infrared light from the light emitter 202 through the light blocking component 214 to the light detector 204, as shown in FIG. 4B.

The light blocking component 214 can be formed to define apertures 220 and 222 positioned over and around the first and second light transmissive components 210 and 212 to allow light to pass through the apertures 220 and 222. By way of a non-limiting example, the aperture 220 over the first light transmissive component 210 can allow light emitted by the light emitter 202 to pass through the first light transmissive component 210 and exit the proximity sensor 200 through the aperture 220 instead of being blocked by the light blocking component 214. Similarly, the aperture 222 over the second light transmissive component 212 can allow light, such as infrared light reflected by a nearby object, to pass through the aperture 222 into the second light transmissive component 212 instead of being blocked by the light blocking component 214, so that the infrared light can pass into the light detector 204.

In addition to the light blocking component 214 inhibiting crosstalk, the presence of the daughterboard 208 can also limit the amount of crosstalk between the light emitter 202 and light detector 204. In some embodiments, material within the base 206 can allow at least a portion of the light emitted by the light emitter 202 to pass through the base 206 underneath the light blocking component 214. Without the presence of the daughterboard 208, the light could pass through the base 206, be reflected into the second light transmissive component 212, and be detected by the light detector 204. By way of a non-limiting example, FIG. 4A depicts an embodiment of a proximity sensor 200 that lacks a daughterboard 208 underneath the light detector 204. In the exemplary embodiment of FIG. 4A, a portion of the light emitted by the light emitter 202 can pass through the first light transmissive component 210 and can be reflected through the base 206 underneath the light blocking component 214, such that it can enter the second light transmissive component 212 from below. The light entering the second light transmissive component 212 can be reflected by the edges of the light blocking component 214 and/or second light transmissive component 212, and can enter the light detector 204, where it can be detected as crosstalk.

However, the placement of the daughterboard 208 below the light detector 204 can inhibit crosstalk. The daughterboard 208 and the surrounding light blocking component 214 can block some or all light transmission from below, such that light originating from the light emitter 202 can be inhibited from reflecting through the proximity sensor 200 and entering the light detector 204. By way of a non-limiting example, FIG. 4B shows an embodiment of a proximity sensor that comprises a daughterboard 208 underneath the light detector 204. In contrast to the light paths of FIG. 4A, FIG. 4B illustrates that the daughterboard 208 can inhibit light that has been reflected through the base 206 underneath the light blocking component 214 from being reflected from below into the second light transmissive component 212 and into the light detector 204.

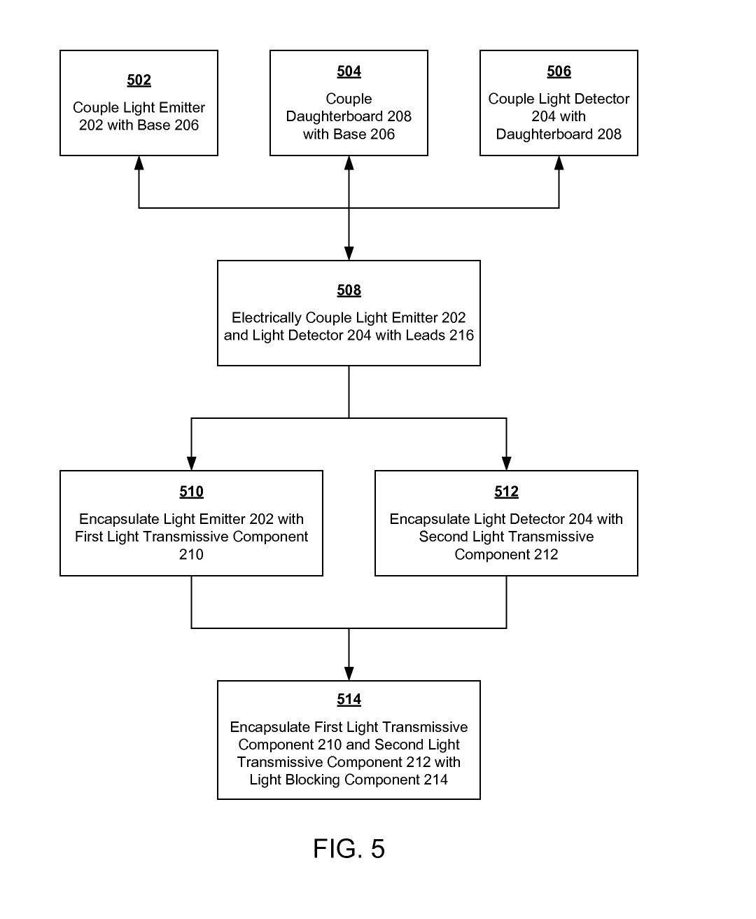

FIG. 5 depicts a flow chart of a first method for manufacturing embodiments of the proximity sensor 200.

At step 502, a light emitter 202 can be coupled with a base 206 and/or leads 216 of a base 206. By way of a non-limiting example, in some embodiments the light emitter 202 can be coupled with one or more leads 216 before the leads 216 are coupled with the rest of the base 206 as shown in FIG. 6A, and the spaces between the leads 216 can then be filled in with other material to form the base 206 as shown in FIG. 6B. In other embodiments, the base 206 can be pre-formed with leads 216, and the light emitter 202 can be coupled with the pre-formed base 206. By way of a non-limiting example, the light emitter 202 can be mounted to the top of the base 206 using adhesives, screws, bolts, solder, or any other coupling mechanism.

At step 504, a daughterboard 208 can be coupled with the base 206 and/or leads 216 of a base 206. By way of a non-limiting example, the daughterboard 208 can be coupled with one or more leads 216 as shown in FIG. 6A, or be mounted to the top of a pre-formed base 206 using adhesives, screws, bolts, solder, or any other coupling mechanism. In some embodiments, spacers can be positioned between the daughterboard 208 and the leads 216, while in other embodiments the daughterboard 208 can be mounted directly on the base 206.

At step 506, a light detector 204 can be coupled with the daughterboard 208. By way of a non-limiting example, the light detector 204 can be mounted on the top of the daughterboard 208 using adhesives, screws, bolts, solder, or any other coupling mechanism.

At step 508, the light emitter 202 and the light detector 204 can be electrically coupled with one or more leads 216 of the base 206, if the light emitter 202 or light detector 204 were not already electrically coupled with the leads 216 during the previous steps. In some embodiments, the light emitter 202 and light detector 204 can be electrically coupled with the leads 216 via wirebonding 218, conductive solder, or any other type of electrical connection. In some embodiments, wirebonding 218 between the light detector 204 and the leads 216 can pass around the daughterboard 208. In other embodiments, wirebonding 218 between the light detector 204 and the leads 216 can pass through apertures in the daughterboard 208. In still other embodiments, the light detector 204 can be electrically coupled to the daughterboard 208 using wirebonding 218, conductive solder, or any other electrical connection, and the daughterboard 208 itself can be electrically coupled with the leads 216.

Steps 502-508 can be performed in any desired order to form an assembly with the light emitter 202 mounted on the base 206 and the light detector 204 mounted on a daughterboard 208 that is itself mounted on the base 206, such that the daughterboard 208 is positioned between the light detector 204 and the base 206, as shown in FIG. 6A-6C.

At step 510, the light emitter 202 can be encapsulated by a first light transmissive component 210. In some embodiments, an optically transmissive compound can be molded and cured over and around the light emitter 202 and at least a portion of the base 206, as shown in FIG. 6B. In some embodiments, the first light transmissive component 210 can be molded to form a dome or lens at its top, while in other embodiments the dome or lens can be absent. The optically transmissive compound of the first light transmissive component 210 can be molded over the light emitter 202 and base 206 using a transfer molding machine or any other suitable molding device.

At step 512, the light detector 204 can be encapsulated by a second light transmissive component 212. In some embodiments, an optically transmissive compound can be molded and cured over and around the light detector 204 and at least a portion of the daughterboard 208, as shown in FIG. 6B. In some embodiments, the second light transmissive component 212 can be molded to form a dome or lens at its top, while in other embodiments the dome or lens can be absent. The optically transmissive compound of the second light transmissive component 212 can be molded over the light detector 204 and daughterboard 208 using a transfer molding machine or any other suitable molding device. FIG. 6B depicts an embodiment of the proximity sensor 200 after steps 510 and 512, which shows the light emitter 202 and light detector 204 encapsulated by the first and second light transmissive components 210 and 212 respectively.

At step 514, after the first and second light transmissive components 210 and 212 have been formed and have cured, the light blocking component 214 can be molded and cured over and around the first and second light transmissive components 212 and 212, the daughterboard 208, and the base 206 to form a proximity sensor 200, as shown in FIGS. 6C and 6D. The optically non-transmissive material of the light blocking component 214 can be molded to fill the space between the first and second light transmissive components 210 and 212 with the light blocking component 214 and to surround the sides of the daughterboard 208 that are not covered by the first or second light transmissive components 210 and 212. In some embodiments, the light blocking component 214 can also be molded to form the exterior surfaces of the proximity sensor 200. FIG. 6C depicts the light blocking component 214 as transparent for illustration purposes to allow the interior components to be seen, while FIG. 6D depicts the exterior of the proximity sensor 200 with the light blocking component 214 as visually opaque.

The light blocking component 214 can be molded to form apertures 220 and 222 in the light blocking component 214 above the light emitter 202 and the light detector 204, as shown in FIG. 6C. Domes of the first and second light transmissive components 210 and 212 can extend into the apertures 220 and 222 in the light blocking component 214. The optically non-transmissive material of the light blocking component 214 can be molded over the first and second light transmissive components 210 and 212 and base 206 using a transfer molding machine or any other suitable molding device. FIG. 6C depicts an embodiment of an embodiment of the proximity sensor 200 after step 514, with the light blocking component 214 molded and cured around the first and second light transmissive components 210 and 212 while leaving the first and second light transmissive components 210 and 212 partially exposed by the apertures 220 and 222.

In some embodiments, each proximity sensor 200 can be manufactured individually. In other embodiments, sheets of proximity sensors 200 can be formed together, with steps 502-514 each being performed multiple times to form each individual proximity sensor 200 on the sheet. After the sheet has been formed and its components have cured, the proximity sensors 200 can be singulated using a precision saw machine, metal stamping machine, or any other desired method. In other embodiments, individual components or modules comprising multiple components can be produced together in sheets, and the components or modules can be singulated and then combined with other components to form individual proximity sensors 200.

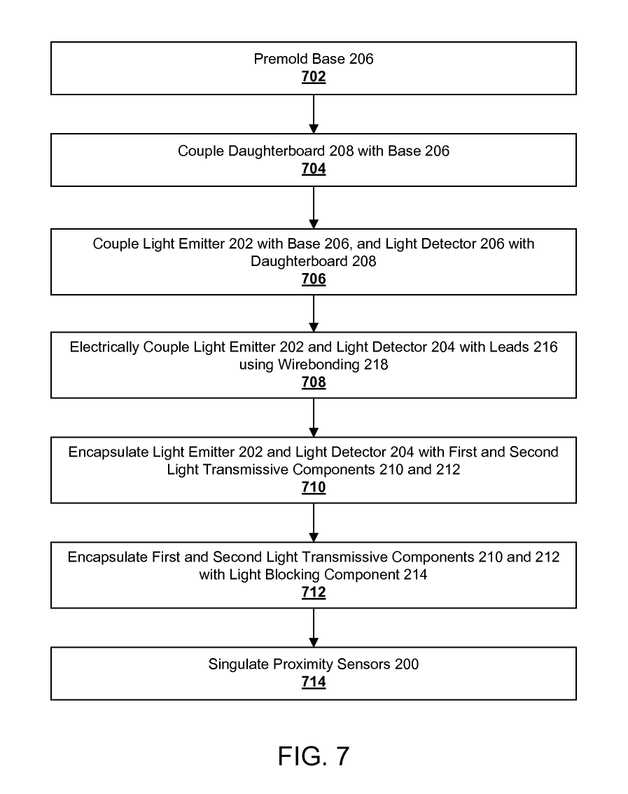

FIG. 7 depicts a flow chart of a second method for manufacturing embodiments of the proximity sensor 200.

At step 702, the base 206 can be pre-formed. As discussed above, in some embodiments the base 206 can be a pre-formed metal leadframe, while in other embodiments the base 206 can be a substrate of laminated organic material or any other desired material. By way of a non-limiting example, in some embodiments the base 206 can be formed with metal conductive leads 216 or metal trace I/O components spaced within a substrate of organic material.

At step 704, the daughterboard 208 can be coupled with the base 206 and/or leads 216 of the base 206. By way of a non-limiting example, the daughterboard 208 can be mounted to the top of the base 206 using conductive adhesives, solder, or any other coupling mechanism. In some embodiments, spacers can be positioned between the daughterboard 208 and the leads 216, while in other embodiments the daughterboard 208 can be mounted directly on the base 206.

At step 706, a light emitter 202 and light detector 204 can be coupled to the base 206 and daughterboard 208 respectively. By way of a non-limiting example, the light emitter 202 and light detector 204 can be mounted to the top of the base 206 and daughterboard 208 using non-conductive or conductive adhesives, solder, or any other coupling mechanism. The light emitter 202 can be mounted directly on the base 206 on one portion of the base 206, while the light detector 204 can be mounted directly on the daughterboard 208 already mounted on a different portion of the base 206 during step 704.

At step 708, the light emitter 202 and light detector 204 can be electrically coupled to leads 216 within the base 206. Wirebonding 218, conductive solder, or any other desired electrical connection method can be used to electrically couple the light emitter 202 to one or more leads 216. In some embodiments, wirebonding 218 or any other electrical connection mechanism can also be used to electrically couple the light detector 204 to one or more leads around or through the daughterboard 208. In other embodiments, wirebonding 218 or any other electrical connection mechanism can be used to electrically couple the light detector 204 to the daughterboard 208, which itself can be electrically coupled to one or more leads 216.

At step 710, the light emitter 202 and light detector 204 can respectively be encapsulated by first and second light transmissive components 210 and 212. As discussed above, in some embodiments the first and second light transmissive components 210 and 212 can be molded and cured, or otherwise be formed, over other components. The first light transmissive component 210 can encapsulate the light emitter 202 over the base 206. The second light transmissive component 212 can encapsulate the light detector 204 over the daughterboard 208 and/or base 206. In some embodiments first and second light transmissive components 210 and 212 can be separately molded. In alternate embodiments the first and second light transmissive components 210 and 212 can be formed together and then a slot or groove can be cut to separate them.

At step 712, the first and second light transmissive components 210 and 212 can be encapsulated with a light blocking component 214 to form a proximity sensor 200. The light blocking component 214 can be molded and cured or otherwise formed over the first and second light transmissive components 210 and 212, such that the space between the first and second light transmissive components 210 and 212 is filled by the light blocking component 214. The light blocking component 214 can also be molded to form apertures 220 and 222 in the light blocking component 214 above the light emitter 202 and the light detector 204.

At step 714, if the above steps were repeated to form a connected sheet of multiple proximity sensors 200, the sheet can be singulated to separate the individual proximity sensors 200. By way of a non-limited example, at step 702 multiple bases 206 for multiple proximity sensors 200 can be pre-formed as a continuous sheet, and the subsequent steps can be followed to build each proximity sensor 200 above the continuous sheet of bases 206. The continuous sheet can be singulated with a precision saw machine, metal punching machine, or any other desired method to separate each proximity sensor 200.

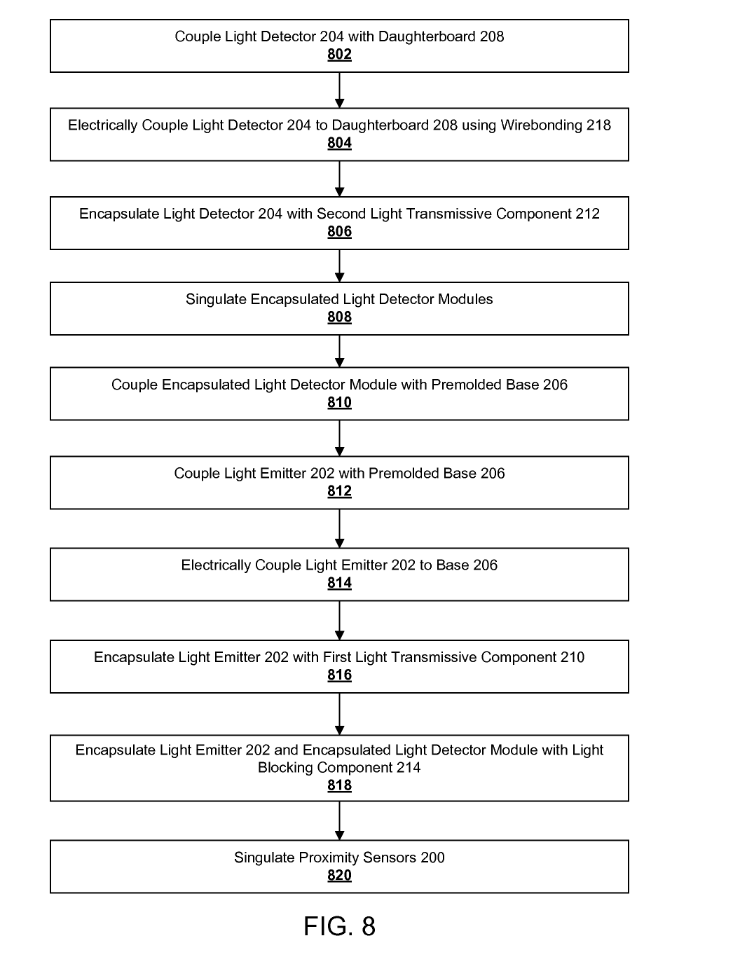

FIG. 8 depicts a flow chart of a third method for manufacturing embodiments of the proximity sensor 200.

At step 802, a light detector 204 can be coupled with a daughterboard 208. By way of a non-limiting example, the light detector 204 can be mounted to the top of the daughterboard 208 using adhesives, solder, or any other coupling mechanism.

At step 804, the light detector 204 can be electrically coupled with the daughterboard 208. In some embodiments, wire bonds 218 can be affixed to conductive portions of the light detector 204 and the daughterboard 208. In other embodiments, conductive solder or any other electrical connection can be used to electrically couple the light detector 204 with the daughterboard 208.

At step 806, the light detector 204 can be encapsulated on the daughterboard 208 with a light transmissive component, such as the second light transmissive component 212. As discussed above, in some embodiments light transmissive components can be molded and cured, or otherwise be formed, over other components. The combination of the light detector 204, daughterboard 208, and light transmissive component can form an encapsulated light detector module.

At step 808, if more than one encapsulated light detector module was formed during steps 802-806, the encapsulated light detector modules can be separated by singulation. By way of a non-limiting example, in some embodiments and/or situations a continuous sheet comprising multiple daughterboards 208 can be used during step 802, with subsequent steps being followed to create multiple encapsulated light detector modules over each daughterboard 208 on the continuous sheet. The continuous sheet can be singulated with a precision saw machine, metal punching machine, or any other desired method to separate each encapsulated light detector module.

At step 810, an encapsulated light detector module can be coupled to a base 206. In some embodiments, the base 206 can be a preformed leadframe or substrate comprising leads 216. The encapsulated light detector module can be mounted to the top of the base 206 using adhesives, solder, or any other coupling mechanism. The daughterboard 208 can be at the bottom of the encapsulated light detector module, such that conductive elements of the daughterboard 208 can be electrically coupled with the leads 216 of the base 206, thereby electrically connecting the light detector within the encapsulated light detector module with the base 206.

At step 812, a light emitter 202 can be coupled with the base 206. By way of a non-limiting example, the light emitter 202 can be mounted to the top of the base 206 using adhesives, screws, bolts, solder, or any other coupling mechanism. The light emitter 202 can be mounted directly on the base 206 on one portion of the base 206, while the encapsulated light detector module can be mounted on a different portion of the base 206 during step 810.

At step 814, the light emitter can be electrically coupled to leads 216 within the base 206. Wirebonding 218, conductive solder, or any other desired electrical connection method can be used to electrically couple the light emitter 202 to one or more leads 216.

At step 816, the light emitter 202 can be encapsulated by a light transmissive component, such as the first light transmissive component 210. As discussed above, in some embodiments light transmissive components can be molded and cured, or otherwise be formed, over other components. The first light transmissive component 210 can encapsulate the light emitter 202 over the base 206.

At step 818, the first light transmissive components 210 encapsulating the light emitter 202 and the encapsulated light detector module can both be encapsulated with a light blocking component 214 to form a proximity sensor 200. The light blocking component 214 can be molded and cured or otherwise formed over the first light transmissive component 210 and the encapsulated light detector module, such that the space between the first light transmissive component 210 and the encapsulated light detector module is filled by the light blocking component 214. The light blocking component 214 can also be molded to form apertures 220 and 222 in the light blocking component 214 above the light emitter 202 and the light detector 204.

At step 820, if the above steps were repeated to form a connected sheet of multiple proximity sensors 200, the sheet can be singulated to separate the individual proximity sensors 200. By way of a non-limited example, at step 810 multiple encapsulated light detector modules, such as ones separated during singulation step 808, can have been coupled with a continuous sheet comprising multiple bases 206, and the subsequent steps can be followed to build each proximity sensor 200 above the continuous sheet of bases 206. The continuous sheet can be singulated with a precision saw machine, metal punching machine, or any other desired method to separate each proximity sensor 200.

Although the invention has been described in conjunction with specific embodiments thereof, it is evident that many alternatives, modifications and variations will be apparent to those skilled in the art. Accordingly, the invention as described and hereinafter claimed is intended to embrace all such alternatives, modifications and variations that fall within the spirit and broad scope of the appended claims.

What is claimed is:

1. An optical proximity sensor, comprising:
an infrared light emitter mounted on a base;
a daughterboard mounted on said base;
an infrared light detector mounted on said daughterboard, such that said daughterboard is positioned between said base and said infrared light detector;
a first infrared light transmissive component encapsulating said infrared light emitter;
a second infrared light transmissive component encapsulating said infrared light detector; and
an infrared light blocking component at least partially encapsulating said first infrared light transmissive component and said second infrared light transmissive component, wherein said infrared light blocking component fills a space between said first infrared light transmissive component and said second infrared light transmissive component, such that infrared light emitted by said infrared light emitter is at least partially blocked from directly entering said second infrared light transmissive component by said infrared light blocking component.

2. The optical proximity sensor of claim 1, wherein said daughterboard is comprised of a light-blocking material such that infrared light passing through said base is at least partially blocked from entering said second infrared light transmissive component from below by said daughterboard.

3. The optical proximity sensor of claim 1, wherein said light blocking component has a first aperture over said light emitter and a second aperture over said light detector.

4. The optical proximity sensor of claim 1, wherein said base is a metal leadframe comprising a plurality of leads.

5. The optical proximity sensor of claim 1, wherein said base comprises organic material.

6. A process of manufacturing an optical proximity sensor, comprising:
coupling a light emitter with a base comprising a plurality of leads;
coupling a daughterboard with said base;
coupling a light detector with said daughterboard;
electrically coupling said light emitter and said light detector with one or more of said plurality of leads;
encapsulating said light emitter with a first light transmissive component;
encapsulating said light detector with a second light transmissive component; and
encapsulating said first light transmissive component and said second light transmissive component with a light blocking component,
wherein said light blocking component fills a space between said first light transmissive component and said second light transmissive component.

7. The optical proximity sensor of claim 5, wherein said daughterboard is comprised of a light-blocking material configured to at least partially block the transmission of infrared light.

8. The optical proximity sensor of claim 5, wherein said light blocking component is formed with a first aperture over said light emitter and a second aperture over said light detector.

9. A process of manufacturing an optical proximity sensor, comprising:
forming a base comprising a plurality of leads;
coupling a daughterboard with said base;
coupling a light emitter to said base and electrically coupling said light emitter to one or more of said plurality of leads;
coupling a light detector to said daughterboard and electrically coupling said light detector to one or more of said plurality of leads;
encapsulating said light emitter with a first light transmissive component;
encapsulating said light detector with a second light transmissive component; and
encapsulating said first light transmissive component and said second light transmissive component with a light blocking component,
wherein said light blocking component fills a space between said first light transmissive component and said second light transmissive component.

10. The optical proximity sensor of claim 9, wherein said daughterboard is comprised of a light-blocking material configured to at least partially block the transmission of infrared light.

11. The optical proximity sensor of claim 9, wherein said light blocking component is formed with a first aperture over said light emitter and a second aperture over said light detector.

12. A process of forming an optical proximity sensor, comprising:
forming an encapsulated light detector module by electrically coupling a light detector with a daughterboard and encapsulating said light detector over said daughterboard with a light transmissive component;
coupling said encapsulated light detector module with a base comprising a plurality of leads, and electrically coupling said light detector with one or more of said plurality of leads;
coupling a light emitter with said base, and electrically coupling said light emitter with one or more of said plurality of leads;
encapsulating said light emitter with a separate light transmissive component; and
encapsulating said encapsulated light detector module and said separate light transmissive component with a light blocking component,
wherein said light blocking component fills a space between said encapsulated light detector module and said separate light transmissive component.

13. The optical proximity sensor of claim 12, wherein said daughterboard is comprised of a light-blocking material configured to at least partially block the transmission of infrared light.

14. The optical proximity sensor of claim 12, wherein said light blocking component is formed with a first aperture over said light emitter and a second aperture over said light detector.
